(19) United States
(12) Patent Application Publication
(10) Pub. No.: US 2011/0284957 A1
(43) Pub. Date: Nov. 24, 2011

(54) SEMICONDUCTOR DEVICE AND METHOD FOR MANUFACTURING THE SAME

(75) Inventors: Tomohiro TAMAKI, Kanagawa (JP); Yoshito NAKAZAWA, Kanagawa (JP); Satoshi EGUCHI, Kanagawa (JP)

(73) Assignee: RENESAS ELECTRONICS CORPORATION, Kanagawa (JP)

(21) Appl. No.: 13/093,073

(22) Filed: Apr. 25, 2011

(30) Foreign Application Priority Data
May 20, 2010 (JP) 2010-116466

(51) Int. Cl. H01L 29/78; H01L 21/78

(52) U.S. Cl. 257/339; 438/462; 257/E29.256; 257/E21.599

(57) ABSTRACT

To fabricate a power MOSFET, etc. high in voltage-proofing (or breakdown voltage) and low in ON resistance (or On-state resistance) by a trench filling method, trial manufacture of power MOSFETs, etc. has been repeated with varying internal structures and layouts of super junction structures in a chip inner region located inside a guard ring. As a result, there occasionally occurred a source-drain voltage-proofing defect attributable to outer end portions of a supper junction structure. In one aspect of the present invention there is provided a semiconductor device having a power semiconductor element with a super junction structure introduced substantially throughout the whole surface of a drift region, the super junction structure being provided substantially throughout the whole surfaces of end portions of a semiconductor chip which configures the semiconductor device.

### CROSS-REFERENCE TO RELATED APPLICATIONS

The disclosure of Japanese Patent Application No. 2010-116466 filed on May 20, 2010 including the specification, drawings and abstract is incorporated herein by reference in its entirety.

### BACKGROUND

The present invention relates to a technique applicable effectively to a chip region periphery laying out technique or a high voltage-proofing technique (or a high breakdown voltage technique) in a semiconductor device (or a semiconductor integrated circuit device) and a method for manufacturing the semiconductor device (or the semiconductor integrated circuit device).

In Japanese Patent Laid-Open No. 2007-116190 (Patent Document 1) or U.S. Patent Laid-Open No. 2005-98826 (Patent Document 2) there are disclosed various structures in connection with cell region periphery layout in a power MOSFET (Metal Oxide Semiconductor Field Effect Transistor) having a super junction structure formed by a multi-epitaxy method or a trench insulating film burying method (intra-trench ion implanting method). Examples are a P⁻ resurf region, a linear peripheral P type drift region of a vertical array formed by a trench insulating film burying method, and a linear peripheral P type drift region of a divided vertical/parallel array.

In Japanese Patent Laid Open No. 2001-298190 (Patent Document 3) or U.S. Patent Laid Open No. 2001-28083 (Patent Document 4) there is disclosed a technique which, in connection with chip layout in a power MOSFET manufactured by a multi-epitaxy method and having a super junction structure, prevents leakage from periphery by forming a super junction structure up to near outer ends of a chip and by making the outermost periphery portion a surrounding area of an N type high concentration and a low resistance different from a P or N type column region.

Japanese Patent Laid-Open No. 2006-324432 (Patent Document 5) discloses a technique which, in connection with chip layout in a power MOSFET manufactured by a trench filling method and having a super junction structure, prevents leakage from periphery by forming a super junction structure up to near outer ends of a chip and by making the outermost periphery portion a surrounding area of an N type high concentration and a low resistance different from a P or N type column region.

### SUMMARY

In connection with a drift region of , for example, a power MOSFET, it is an important subject to avoid the restrictions by the conventional silicon limit and develop a high voltage-proof FET (or a high breakdown voltage FET) of a low ON resistance (or a low ON-state resistance). To solve this problem, various methods have been developed which introduce into the drift region a super junction structure having slab-like N and P type column regions of a relatively high concentration alternately. Roughly speaking, as super junction structure introducing methods there are three kinds of methods, which are multi-epitaxial method, trench insulating film burying method, and trench filling method (trench epitaxial burying method). Of these methods, the multi-epitaxial method, which repeats epitaxial growth and ion implantation many times, is high in the degree of freedom of process and design, but is so much complicated in its manufacturing process and is hence high in cost. In the trench insulating film burying method, after oblique ion implantation into a trench, the trench is filled up with an insulating film by CVD (Chemical Vapor Deposition). This method is simple in point of process, but is disadvantageous in point of area because the area increases by the area of the trench.

On the other hand, the trench method is relatively low in the degree of freedom of process and design due to restrictions on conditions for burying epitaxial growth, but has a merit that the manufacturing process is simple. In view of this point the inventors in the present case have studied problems in device structure and mass production of a power MOSFET, etc. with respect to high voltage-proofing (or high breakdown voltage) and low ON resistance (or low ON-state resistance) based on the trench filling method. As a result, it turned out that there was the following problem. In the super junction structure, the concentration of a body cell portion (active region) becomes relatively high, therefore, with the conventional junction edge termination structure or resurf structure (reduced surface field), it is difficult to ensure at a periphery portion (peripheral region, junction terminal region) a breakdown voltage equal to or higher than that in the cell portion.

In view of the above point the inventors in the present case have repeated trial fabrications of power MOSFETS with varying internal structures and layouts of super junction structures in a chip inner region located inside a guard ring. As a result there occasionally occurred a source-drain voltage-proof defect attributable to outer end portions of a super junction structure. As a result of having analyzed the defective chip concerned it turned out that there was a depression in the surface of a P type column region 6 located at the outermost periphery and that a crystal defect extended 20 to 30 micrometers obliquely downwards toward the interior of the chip at an angle of about 45° starting from that depression.

The present invention has been accomplished for solving the above-mentioned problems.

It is an object of the present invention to provide a semiconductor device such as a solid active element of high voltage-proofing (or high breakdown voltage) and low ON resistance (or low ON-state resistance).

The above and other objects and novel features of the present invention will become apparent from the following description and the accompanying drawings.

Of the inventions disclosed herein, a typical one will be outlined below.

In one aspect of the present invention there is provided a semiconductor device having a power semiconductor element with a super junction structure introduced substantially throughout the whole surface of a drift region, the super junction structure being provided substantially throughout the whole surfaces of end portions of a semiconductor chip which configures the semiconductor device.

The following is a brief description of an effect obtained by the typical invention.

In the semiconductor device having a power semiconductor element with a super junction structure introduced substantially throughout the whole surface of a drift region, since the super junction structure is provided substantially throughout the whole surfaces of end portions of a semiconductor chip which configures the semiconductor device, it is possible to prevent the occurrence of a depression or the like in the surface of a P type column region located at the outermost periphery.

### BRIEF DESCRIPTION OF THE DRAWINGS

FIG. 1 s a schematic layout diagram of device chip upper surface electrodes, etc. of a power MOSFET as an example of a semiconductor device (a basic form of a two-dimensional resurf structure) according to a first embodiment of the present invention;

FIG. 2 is a schematic layout diagram of device chip upper surface impurity regions, etc. with upper surface aluminum-based metal electrodes, etc. removed from FIG. 1 to make the layout of impurity regions on a semiconductor substrate easier to see;

FIG. 3 is a partial enlarged schematic layout diagram of device chip upper surface impurity regions, etc. in a chip corner cut-off region R1 in FIG. 2;

FIG. 4 is a sectional diagram of the chip corresponding to X-X′ section in FIG. 3;

FIG. 5 is a partial enlarged schematic layout diagram of wafer upper surface impurity regions, etc. in and around a corner portion of a chip region on a wafer corresponding to FIG.

3;

FIG. 6 is a sectional view of the wafer corresponding to X-X′ section (showing up to this side of an adjacent chip region) in FIG. 5;

FIG. 7 is a partial sectional view of the wafer in a wafer process (a P type column trench-forming hard mask film forming step) corresponding to X-X′ section (showing up to near a guard ring in an adjacent chip region) in FIG. 5 in connection with a method for manufacturing the semiconductor device according to the first embodiment;

FIG. 8 is a partial sectional view of the wafer in the wafer process (a P type column trench-forming hard mask film patterning step) corresponding to X-X′ section (showing up to near the guard ring in the adjacent chip) in FIG. 5 in connection with the method for manufacturing the semiconductor device according to the first embodiment;

FIG. 9 is a partial sectional view of the wafer in the wafer process (a P type column trench forming step) corresponding to X-X′ section (showing up to near the guard ring in the adjacent chip region) in FIG. 5 in connection with the method for manufacturing the semiconductor device according to the first embodiment;

FIG. 10 is a partial sectional view of the wafer in the wafer process (a P type burying epitaxial growth step) corresponding to X-X′ section (showing up to near the guard ring in the adjacent chip region) in FIG. 5 in connection with the method for manufacturing the semiconductor device according to the first embodiment;

FIG. 11 is a partial sectional view of the wafer in the wafer process (a planarization step) corresponding to X-X′ section (showing up to near the guard ring in the adjacent chip region) in FIG. 5 in connection with the method for manufacturing the semiconductor device according to the first embodiment;

FIG. 12 is a partial sectional view of the wafer in the wafer process (a P⁻ type surface resurf region introducing step) corresponding to X-X′ section (showing up to near the guard ring in the adjacent chip region) in FIG. 5 in connection with the method for manufacturing the semiconductor device according to the first embodiment;

FIG. 13 is a partial sectional view of the wafer in the wafer process (a field insulating film etching step) corresponding to X-X′ section (showing up to near the guard ring in the adjacent chip region) in FIG. 5 in connection with the method for manufacturing the semiconductor device according to the first embodiment;

FIG. 14 is a partial sectional view of the wafer in the wafer process (a P type body region introducing step) corresponding to X-X′ section (showing up to near the guard ring in the adjacent chip region) in FIG. 5 in connection with the method for manufacturing the semiconductor device according to the first embodiment;

FIG. 15 is a partial sectional view of the wafer in the wafer process (a gate electrode forming step) corresponding to X-X′ section (showing up to near the guard ring in the adjacent chip region) in FIG. 5 in connection with the method for manufacturing the semiconductor device according to the first embodiment;

FIG. 16 is a partial sectional view of the wafer in the wafer process (an N⁺ source region introducing step) corresponding to X-X′ section (showing up to near the guard ring in the adjacent chip region) in FIG. 5 in connection with the method for manufacturing the semiconductor device according to the first embodiment;

FIG. 17 is a partial sectional view of the wafer in the wafer process (an interlayer dielectric film forming step) corresponding to X-X′ section (showing up to near the guard ring in the adjacent chip region) in FIG. 5 in connection with the method for manufacturing the semiconductor device according to the first embodiment;

FIG. 18 is a partial sectional view of the wafer in the wafer process (a body contact hole forming step) corresponding to X-X′ section (showing up to near the guard ring in the adjacent chip region) in FIG. 5 in connection with the method for manufacturing the semiconductor device according to the first embodiment;

FIG. 19 is a partial sectional view of the wafer in the wafer process (a P⁺ body contact region introducing step) corresponding to X-X′ section (showing near the guard ring in the adjacent chip region) in FIG. 5 in connection with the method for manufacturing the semiconductor device according to the first embodiment;

FIG. 20 is a partial sectional view of the wafer in the wafer process (an upper surface metal electrodes forming step) corresponding to X-X′ section (showing up to near the guard ring in the adjacent chip region) in FIG. 5 in connection with the method for manufacturing the semiconductor device according to the first embodiment;

FIG. 21 is a partial sectional view of the wafer in the wafer process (a final passivation forming, back grinding and lower surface metal electrode forming step) corresponding to X-X′ section (showing up to near the guard ring in the adjacent chip region) in FIG. 5 in connection with the method for manufacturing the semiconductor device according to the first embodiment;

FIG. 22 is a partial sectional view of the wafer in the wafer process (a dicing step) corresponding to X-X′ section (showing up to near the guard ring in the adjacent chip region) in FIG. 5 in connection with the method for manufacturing the semiconductor device according to the first embodiment;

FIG. 23 is a top view of the entire wafer for explaining crystal orientation of the wafer, etc. in for example the method for manufacturing the semiconductor device according to the first embodiment;

FIG. 24 is a partial sectional view of the wafer (corresponding to a wafer section cut-off region R2 in FIG. 9) for explaining a relation between wafer crystal orientation, etc. and each face of a trench in the method for manufacturing the semiconductor device according to the first embodiment;

FIG. 25 is a partial enlarged schematic layout diagram of device chip upper surface impurity regions, etc. corresponding to FIG. 3 for explaining a modification 1 (a two-dimensional resurf structure) related to a planar layout of a power MOSFET device structure as an example of the semiconductor device according to the first embodiment;

FIG. 26 is a partial enlarged schematic layout diagram of device chip upper surface impurity regions, etc. corresponding to FIG. 3 for explaining a modification 2 (a three-dimensional resurf structure) related to a planar layout of a power MOSFET device structure as an example of the semiconductor device according to the first embodiment;

FIG. 27 is a partial enlarged schematic layout diagram of wafer upper surface impurity regions in and around a corner portion of a chip region on a wafer corresponding to FIG. 5 for explaining a device structure (a two-dimensional resurf structure) of a power MOSFET as an example of a semiconductor device according to a second embodiment of the present invention; and

FIG. 28 is a sectional view of the wafer corresponding to X-X′ section (showing up to near a guard ring in an adjacent chip region) in FIG. 27.

### DETAILED DESCRIPTION

### Outline of Embodiments

First, typical embodiments according to the present invention will be outlined below.

1. A semiconductor device including: (a) a semiconductor substrate having a first main surface and a second main surface and with a power semiconductor element formed thereover; (b) a first electrode of the power semiconductor element provided on the first main surface side of the semiconductor substrate; (c) a drift region of the power semiconductor element, the drift region being provided within a surface on the first main surface side of the semiconductor substrate and having a first conductivity type; and (d) a super junction structure formed substantially throughout the whole surface of the drift region, the super junction structure being provided substantially throughout the whole surfaces of end portions of the semiconductor substrate.
2. In the semiconductor device of the above item 1, the super junction structure reaches outer side faces of the semiconductor substrate.
3. In the semiconductor device of the above item 1 or 2, there is further included: (e) a guard ring formed over the first main surface of the semiconductor substrate so as to extend along an outer periphery of the first main surface.
4. In the semiconductor device of any of the above items 1 to 3, the super junction structure is provided substantially throughout the whole of the first main surface of the semiconductor substrate when seen in plan.
5. In the semiconductor device of the above item 3 or 4, the super junction structure is formed also exteriorly of the guard ring.
6. In the semiconductor device of any of the above items 1 to 5, in which the power semiconductor element is a power MOSFET.
7. In the semiconductor device of any of the above items 1 to 5, the power semiconductor element is a vertical power MOSFET.
8. In the semiconductor device of any of the above items 1 to 7, the super junction structure is formed by an epitaxy trench filling method.
9. A semiconductor device including: (a) a semiconductor substrate having a first main surface and a second main surface and with a power semiconductor element formed thereover; (b) a first electrode of the power semiconductor element, the first electrode being provided on the first surface side of the semiconductor substrate; (c) a drift region of the power semiconductor element, the drift region being provided within a surface on the first main surface side of the semiconductor substrate and having a first conductivity type; (d) a cell region of the power semiconductor element, the cell region being provided in a surface region on the first main surface side of the semiconductor substrate and, when seen in plan, in an inner region of the first main surface of the semiconductor substrate; (e) a cell region periphery impurity doped region provided in the surface region on the first main surface side and, when seen in plan, at a periphery of the cell region so as to surround the cell region; (f) a guard ring provided over and in a peripheral region of the first main surface of the semiconductor substrate so as to surround the cell region periphery impurity doped region; and (g) a super junction structure formed in the drift region inside an outer periphery of the guard ring when seen in plan, each outer end of the super junction structure extending more outwards 40 micrometers or more than an outer periphery of the cell region periphery impurity doped region.
10. In the semiconductor device of the above item 9, the cell region periphery impurity doped region is a surface resurf region.
11. In the semiconductor device of the above item 9 or 10, the super junction structure is formed by an epitaxy trench filling method.
12. In the semiconductor device of any of the above items 9 to 11, the power semiconductor element is a power MOSFET.
13. In the semiconductor device of any of the above items 9 to 12, the power semiconductor element is a vertical power MOSFET.
14. A method for manufacturing a semiconductor device, including the steps of: (a) forming a super junction structure substantially throughout the whole of a first main surface of a semiconductor wafer having the first main surface and a second main surface; (b) after the step (a), forming over the first main surface a plurality of semiconductor chip regions each corresponding to a power semiconductor element and mutually isolated by scribing lines; and (c) after the step (b), separating the semiconductor wafer along the scribing lines to divide the wafer into individual semiconductor chip regions.
15. In the method of the above item 14, the super junction structure is formed by an epitaxy trench filling method.
16. In the method of the above item 14 or 15, the power semiconductor element is a power MOSFET.
17. In the method of any of the above items 14 to 16, the super junction structure is formed substantially throughout the whole surface of each of the semiconductor chip regions and substantially throughout the whole surface within each of the scribing lines.
18. In the method of any of the above items 14 to 17, a guard ring is provided in a peripheral region within each of the semiconductor chip regions.
19. In the method of any of the above items 14 to 18, an alignment pattern forming region not formed with the super junction structure is present within each of the scribing lines.
20. In the method of any of the above items 14, 15 and 17 to 19, the power semiconductor element is a vertical power MOSFET.

### Description Form, Basic Terms, and How to Use, in the Present Invention

1. An embodiment of the present invention may be described dividedly into plural sections where required for the sake of convenience, but unless otherwise mentioned, the divided sections are not independent of each other, but configure portions of a single example, or one is a partial detail of the other or is a modification of part or the whole of the other. As to similar portions, repeated explanations thereof are omitted in principle. Constituent elements in an embodiment are not essential unless otherwise mentioned and except the case where they are limited theoretically to specified numbers thereof, further, except the case where they are clearly essential contextually.

By “semiconductor device” as referred to herein is meant a device including various transistors (active elements) each alone or an integration thereof on a semiconductor chip or the like (e.g., a single crystal silicon substrate) together with, for example, resistors and capacitors. As typical examples of the various transistors are mentioned MISFETs (Metal Insulator Semiconductor Field Effect Transistors) typical of which is MOSFET (Metal Oxide Semiconductor Field Effect Transistor). The present invention uses power semiconductor elements. The “power semiconductor elements” refer mainly to various semiconductor elements handling electric power of 5 W or more, e.g., power MOSFET, IGBT (Insulated Gate Bipolar Transistor), power diode, and composite elements each including at least one of those semiconductor elements.

2. Likewise, in the description of an embodiment or the like, as to “X comprising A” or the like with respect to material or composition, selection of any other element than A as one of principal constituent elements is not excluded unless otherwise mentioned and except the case where a negative answer is evident contextually. For example, as to component, by the above description is meant “X containing A as a principal component.” For example, “silicon member” is not limited to pure silicon, but it goes without saying that the silicon member in question includes SiGe alloy, other multi-element alloys containing silicon as a principal component, and those containing silicon and additives. Likewise, it goes without saying that “silicon oxide film” and “silicon oxide-based insulating film” include not only relatively pure undoped silicon dioxide but also oxide films resulting from thermal oxidation such as FSG (Fluorosilicate Glass), TEOS-based silicon oxide, SiOC (silicon oxicarbide), carbon-doped silicon oxide, OSG (Organosilicate Glass), PSG (Phosphorus Silicate Glass), and BPSG (Bborophosphosilicate Glass), CVD oxide films, coating type silicon oxides such as SOG (Spin ON Glass) and NCS (Nano-Clustering Silica), silica-based low-k insulating films (porous insulating films) containing the same members as just referred to with vacancy introduced therein, and films composited with other silicon-based insulating films containing the same members as referred to above as principal components.

Like the silicon oxide insulating films there also are known silicon nitride insulating films as silicon-based insulating films commonly used in the semiconductor field. As materials of such silicon nitride films there are, for example, SiN, SiCN, SiNH, and SiCNH. By “silicon nitride” is meant to include both SiN and SiNH unless otherwise mentioned.

3. Although suitable examples will be shown as to figure, position and attribute, it goes without saying that no strict limitation is made to those examples unless otherwise mentioned and except the case where it is evident contextually that limitation is made thereto.
4. When reference is made to a specific numerical value or quantity, a numerical value larger or smaller than the specific numerical value will also do unless otherwise mentioned and except the case where limitation is made to the specific numerical value theoretically, further, except the case where a negative answer is evident contextually.
5. By “wafer” is usually meant a single crystal silicon wafer with semiconductor devices (also true of semiconductor integrated circuit devices and electronic devices) formed thereon. However, it goes without saying that the wafer in question includes epitaxial wafers and composite wafers, e.g., a combination of an insulating substrate such as SOI substrate or LCD glass substrate with a semiconductor layer.
6. Generally, the super junction structure indicates a structure in which in a semiconductor region of a certain conductivity type are inserted columnar or plate-like column regions of a counter conductivity type at almost equal intervals to maintain a charge balance. In the present invention, when reference is made to the “super junction structure” formed by a trench filling method, it indicates, in principle, a structure in which in a semiconductor region of a certain conductivity type are inserted plate-like (usually plate-like, but may be bent) “column regions” of a counter conductivity type at nearly equal intervals to maintain a charge balance. In the following embodiments a description will be given about a structure in which P type column regions are formed in parallel at equal intervals in an N type semiconductor layer (e.g., a drift region).

Therefore, by the description “the super junction structure is exposed to chip side faces” is meant not only a case where P type column regions are exposed, but also a case where regions acting as P or N type column regions are exposed to chip side faces.

In connection with the super junction structure, “orientation” indicates a longitudinal direction when P or N type columns which configure the super junction structure are seen two-dimensionally (at a surface parallel to a main surface of a chip or a wafer) correspondingly to the chip main surface.

In the present invention, when reference is made to the drift region, this region includes not only an epitaxy layer portion which becomes a current path in an ON condition of a power semiconductor device such as a power MOSFET, but also a peripheral epitaxy layer portion (incl. P and N type column regions) which contributes to maintaining voltage-proofing in opposite direction in an OFF condition of the power semiconductor device.

In the present invention, in connection with Resurf (Reduced Surface Field) structure or Junction Edge Termination structure, the “junction edge extension” or “surface resurf region (more specifically, P type resurf region)” indicates a region which is formed in a surface region of the drift region and which is coupled to an end portion of a P type body region (P type well region) configuring a channel region, the region in question being the same in conductivity type as and lower in impurity concentration than the P type body region. Usually it is formed in the shape of a ring so as to surround the cell portion.

### Details of the Embodiments

The embodiments of the present invention will be described below in more detail. In the accompanying drawings, the same or similar portions are identified by the same or similar symbols or reference numerals, and repeated explanations thereof will be omitted in principle.

In the accompanying drawings, hatching or the like of even a section may be omitted in the case where the hatching would result in a complicated view or where distinction from a void is clear. In this connection, even in the case of a planarly closed hole, a background contour line may be omitted if the closed state is clear from an explanation or the like. Further, a portion, even if it is not a section, may be hatched to clarify that the portion is not a void.

In the following description, reference will be made, as an example, to products having a breakdown voltage of several hundred volts or so (e.g., 600 volts).

As prior patent applications each disclosing a power MOSFET utilizing the super junction structure there are, for example, Japanese Patent Application No. 2009-263600 (filed Nov. 19, 2009 in Japan), Japanese Patent Application No. 2010-81905 (filed Mar. 31, 2010 in Japan) , and Japanese Patent Application No. 2010-109957 (filed May 12, 2010 in Japan).

### 1. Explanation of Device Structure (Two-dimensional Resurf

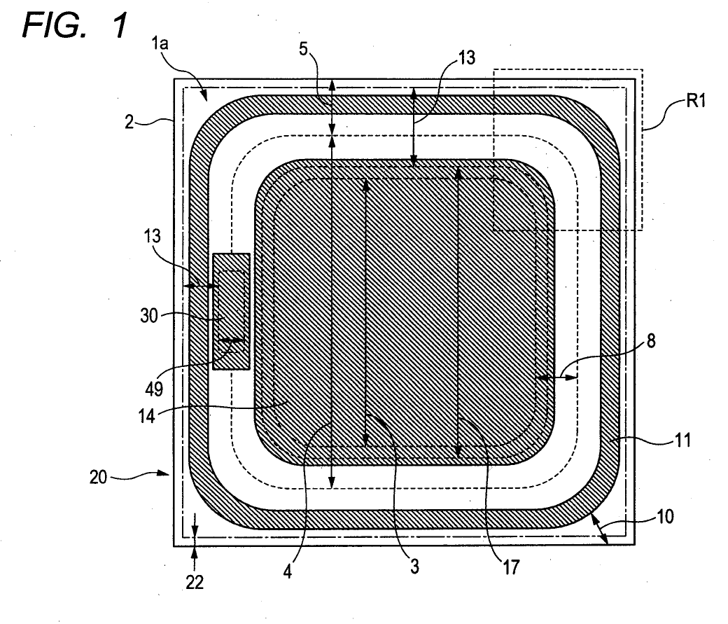

Structure) of Power MOSFET as an example of a semiconductor device according to a first embodiment of the present invention (see mainly FIGS. 1 to 6):

In this embodiment a concrete description will be given while making reference as an example to a planar type vertical power MOSFET formed on a silicon-based semiconductor substrate and having a source-drain breakdown voltage of about 600 volts (this is also true in sections which follow as to a planar type power MOSFET). However, it goes without saying that the following description is applicable also to other power MOSFETs and devices (power semiconductor elements) having other breakdown voltage values.

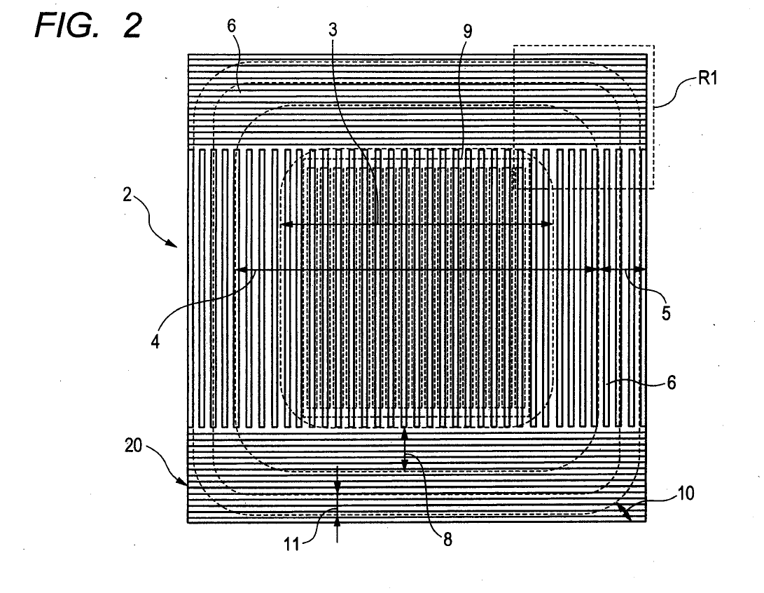

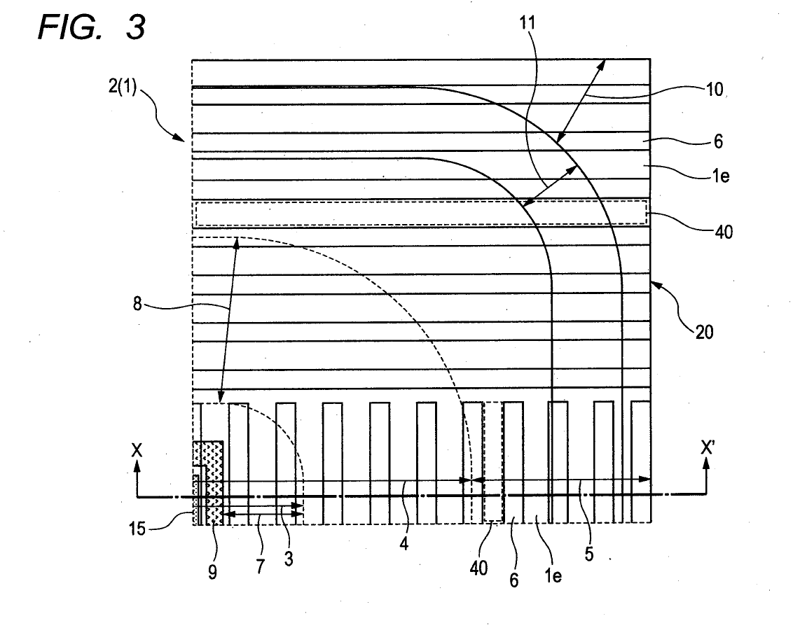

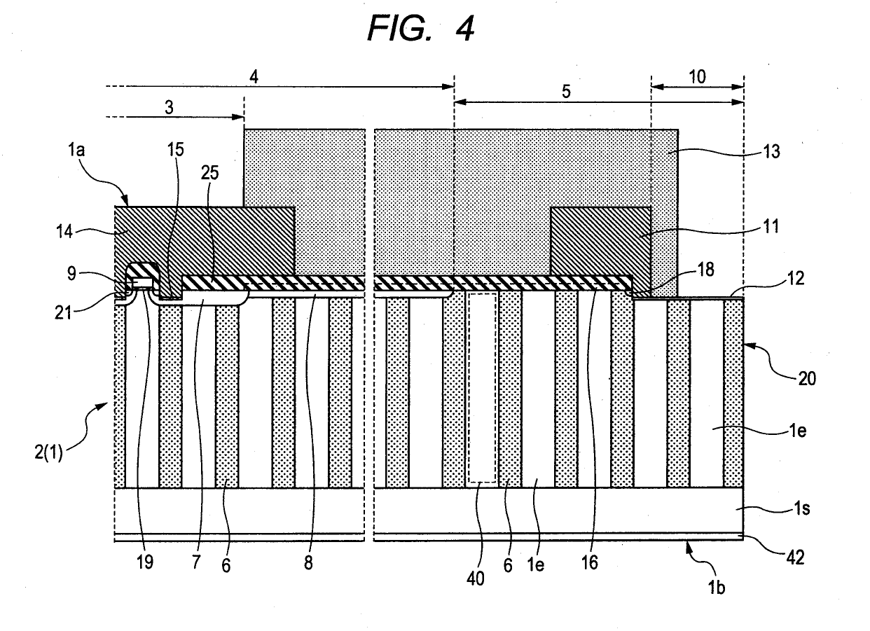

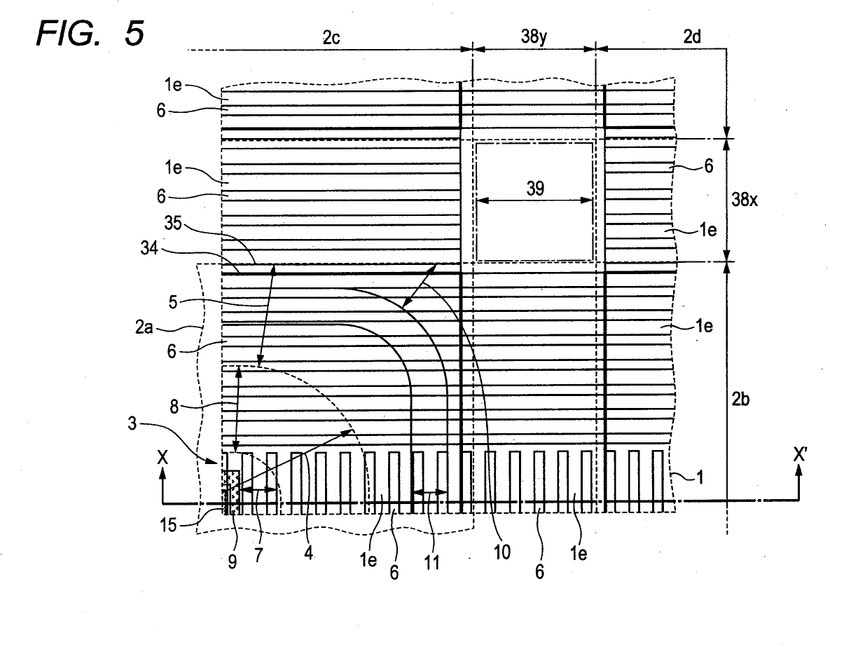

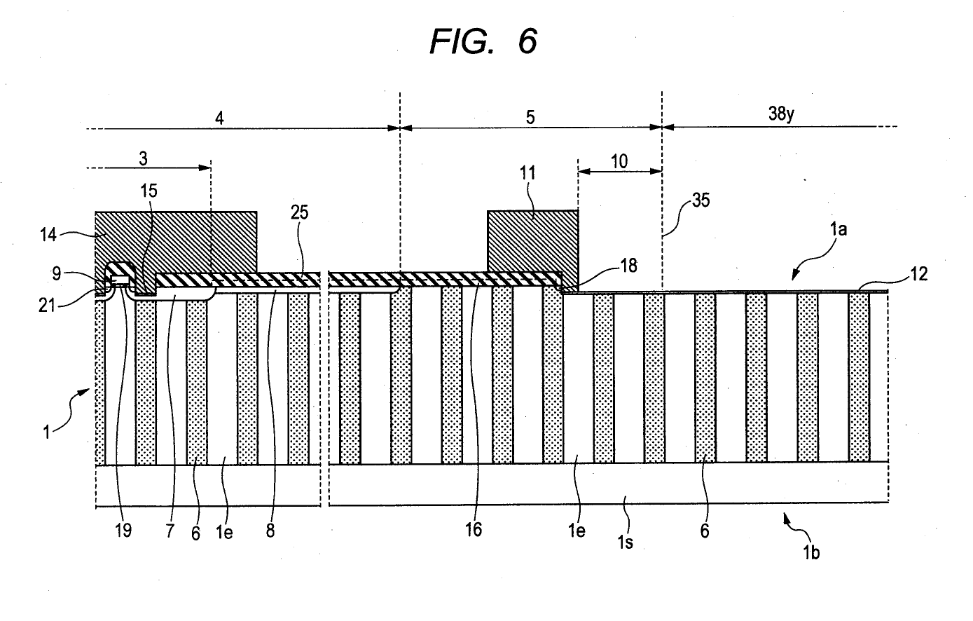

FIG. 1 is a schematic layout diagram of device chip upper surface electrodes, etc. of a power MOSFET as an example of a semiconductor device (a basic form of a two-dimensional resurf structure) according to a first embodiment of the present invention. FIG. 2 is a schematic layout diagram of device chip upper surface impurity regions, etc. with upper surface aluminum-based metal electrodes, etc. removed from FIG. 1 to make the layout of impurity regions on a semiconductor substrate easier to see. FIG. 3 is a partial enlarged schematic layout diagram of device chip upper surface impurity regions, etc. in a chip corner cut-off region R1 in FIG. 2. FIG. 4 is a sectional diagram of the chip corresponding to X-X′ section in FIG. 3. FIG. 5 is a partial enlarged schematic layout diagram of wafer upper surface impurity regions, etc. in and around a corner portion of a chip region on a wafer corresponding to FIG. 3. FIG. 6 is a sectional view of the wafer corresponding to X-X′ section (showing up to this side of an adjacent chip region) in FIG. 5. With reference to these figures, a device structure (a two-dimensional resurf structure) of a power MOSFET as an example of the semiconductor device of this first embodiment will be described below.

Description is directed first to an entire layout (upper surface electrodes layout) of a chip. As shown in FIG. 1, a guard ring 11 is provided at a peripheral portion of a chip 2 (chip region, the chip is 3 mm square as an example) , and a gate metal electrode 30 (metal gate pad) is provided inside the guard ring 11. A central portion of the chip 2 is occupied by a source metal electrode 14 (metal source pad) , and an active cell region 3 is formed in almost all the portion underlying the source metal electrode 14. The portion of an upper surface la of the chip (a semiconductor substrate) other than a source pad aperture 17, a gate pad aperture 49 and a chip periphery aperture 22 (an annular region of a certain width from a boundary between a chip side face 20 and the upper surface 1a) is covered with a final passivation film 13. Further, an annular P⁻type surface resurf region 8 is provided around the active cell region 3. A combined region of the active cell region 3 with the P⁻ type surface resurf region 8 is a chip inner region 4 and the region located outside the chip inner region 4 is a chip periphery region 5. In the chip periphery region 5, the region located outside the guard ring 11 is a chip end portion 10. The details of the chip corner cut-off region R1 (also true of FIG. 2) will be described later in connection with FIG. 3.

Next, with reference to FIG. 2, a description will be given about the layout of a diffusion structure (impurity doped regions) of the upper surface la of the chip 2. As shown in FIG. 2, at a central portion of the upper surface 1a of the chip 1, a plurality of vertically long band-like regions which are almost equal in both width and length are provided periodically at nearly equal intervals from the left to the right end. In upper and lower regions of the upper surface 1a of the chip 2 where the vertically long band-like regions are not spread all over there are periodically provided a plurality of laterally long band-like regions which are almost equal in both width and spacing to the vertically long band-like regions (the laterally long band-like regions are almost equal in length). These vertically long band-like regions and laterally long band-like regions are P type column regions 6. A generally square figure located inside the active cell region 3 and provided in the interior thereof with many vertically long apertures denotes a polysilicon gate electrode 9. The P type column regions 6 are provided substantially throughout the whole surface of the chip 2, even up to the outside of the guard ring 11. Therefore, the P type column regions 6 reach the chip side faces 20 at least partially (see FIG. 3).

Next, reference is here made to FIG. 3, which shows a detailed layout of the chip corner cut-off region R1 in FIG. 2. As shown in FIG. 3, within the active cell region 3 is disposed a polysilicon gate electrode 9 of a power MOSFET (a power semiconductor element) and a P⁺ body contact region 15 (source contact) is provided within an aperture of the polysilicon gate electrode 9. An outer periphery portion of the active cell region 3 serves as an annular P type body region 7 (P type well region) which configures a channel region, etc. Outside the active cell region 3 is provided a P⁻ type surface resurf region 8 so as to adjoin and surround the active cell region 3. As noted previously, in an N type epitaxial layer 1e (drift region) are spread P type column regions 6 substantially throughout the whole surface at nearly constant intervals . The N type epitaxial layer le located between P type column regions 6 acts as an N type column region 40. A super junction structure is comprised of the column regions 6 and the N type column region 40. The super junction structure reaches the side faces of the chip 2 substantially throughout the whole circumference. The super junction structure is also provided outside the guard ring 11.

Referring now to FIG. 4, which is an X-X′ section of FIG. 3, for example on a lower surface of an N⁺ silicon single crystal substrate 1s is provided a back surface metal film 42 (drain electrode) , while on an upper surface of the N⁺ silicon single crystal substrate 1s is formed an N type silicon epitaxial layer 1e. A plurality of P type column regions 6 are buried in the N type silicon epitaxial layer le and the portion between adjacent P type column regions 6 acts as an N type column region 40, both configuring a drift region of the super junction structure. A P type body region 7 is formed in a surface area of the drift region (N type epitaxial layer 1e) in the active cell region 3. On a surface of the P type body region 7 are provided a P⁺ body contact region 15 and an N⁺ source region 21. A P⁻ type surface resurf region 8 is provided in the surface area of the drift region (N type epitaxial layer 1e) at the portion of the chip inner region 4 other than the active cell region 3. A polysilicon gate electrode 9 is provided through a gate insulating film 19 onto the surface of the N type epitaxial layer le located over a pair of N⁺ source regions 21. The portion from an outer end of the P type body region 7 up to near the chip end portion 10 is covered with a field insulating film 16. The polysilicon gate electrode 9 and the upper surface la of the semiconductor substrate 1 are covered from above with an interlayer dielectric film 25 which is a silicon oxide film. An N⁺ source-associated region 18 (channel stop region) of a chip edge portion and a P⁺ body contact-associated region (outermost periphery P⁺ region) 12 of the chip edge portion are provided on the upper surface 1a of the semiconductor substrate 1 in the chip periphery region 5. On the interlayer dielectric film 25 are provided a metal source pad 14 (source metal electrode) and a guard ring (metal guard ring) 11 each formed for example by an aluminum-based metal film. Further, a final passivation film 13 is formed above them. Thus, the super junction structure reaches the side faces 20 of the chip 2.

Next, regions corresponding to FIG. 4 are transferred onto a wafer and will be explained, including their peripheral portions, with reference to FIG. 5 (showing a right upper corner portion of the chip region 2 (2a) in FIG. 3 and an outer periphery region thereof) and FIG. 6 (a partial wafer section corresponding to X-X′ section in FIG. 5, showing, however, a state before formation of the final passivation film unlike FIG. 4). As shown in FIGS. 5 and 6, the right upper corner portion of the chip region 2a is adjacent to chip regions 2b, 2c and 2d with an X-direction scribing region 38x (scribing line) and a Y-direction scribing region 38y (scribing line) among them. For example, in a region where the X- and Y-direction scribing regions 38x, 38y cross each other there is provided an aligning target pattern region 39 (aligning pattern forming region) for alignment between the P type column regions 6 and subsequent steps. The super junction structure is formed substantially throughout the whole area of a surface-side main surface la (a device surface or a first main surface) of the wafer 1 other than the aligning pattern forming region 39. End portions of the scribing lines 38x and 38y correspond to actual outer ends 35 of the chip region and are therefore a little more outside than outer ends 34 of the chip region on a mask pattern.

The aligning target pattern region 39 may be positioned anywhere if only it is on the scribing lines 38, but when it is provided in a crossing region of the scribing lines 38, there accrues a merit that the access of a defect from there to the chip region 2 becomes most difficult.

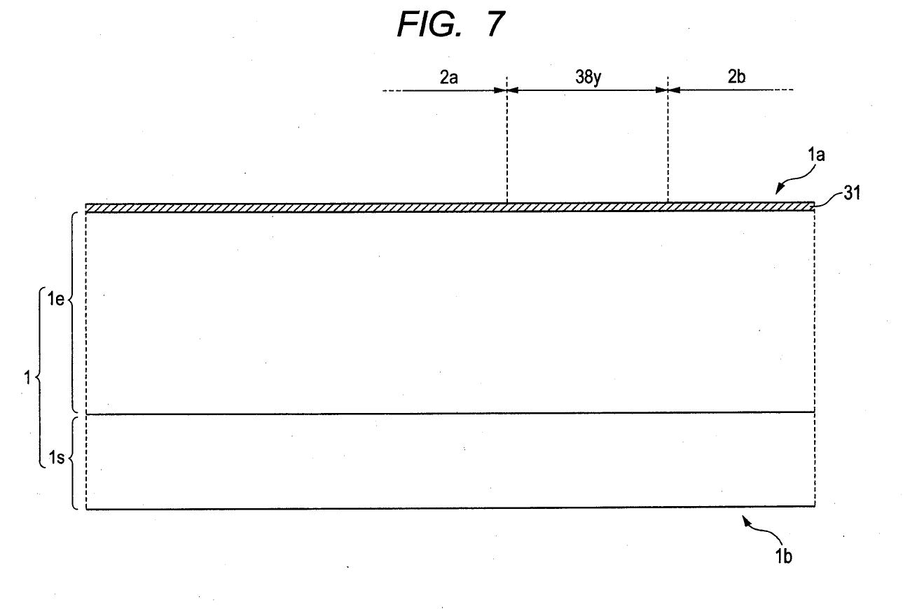

2. Explanation of Wafer Process, etc. in the method for manufacturing the semiconductor device according to the first embodiment (see mainly FIGS. 7 to 22):

In this section a description will be given about a process corresponding to the structure of section 1, but also as to other structural points, since they are basically common, repeated explanations thereof will be omitted.

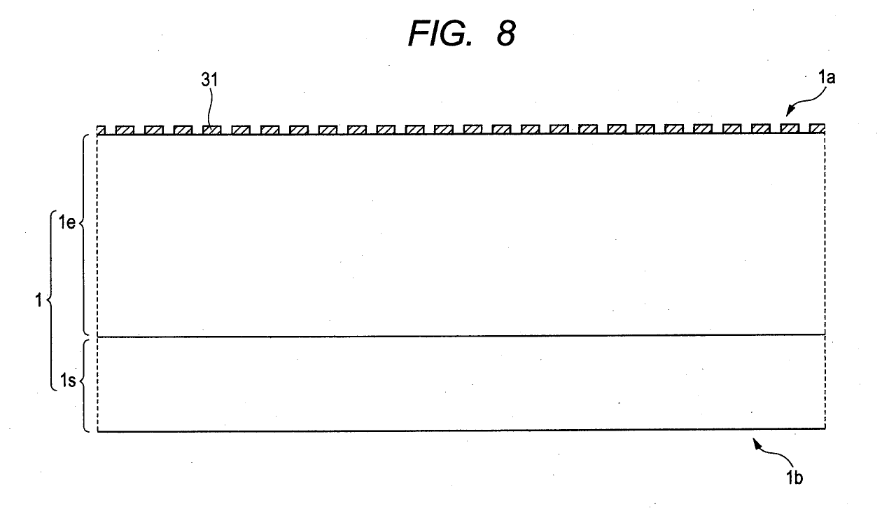

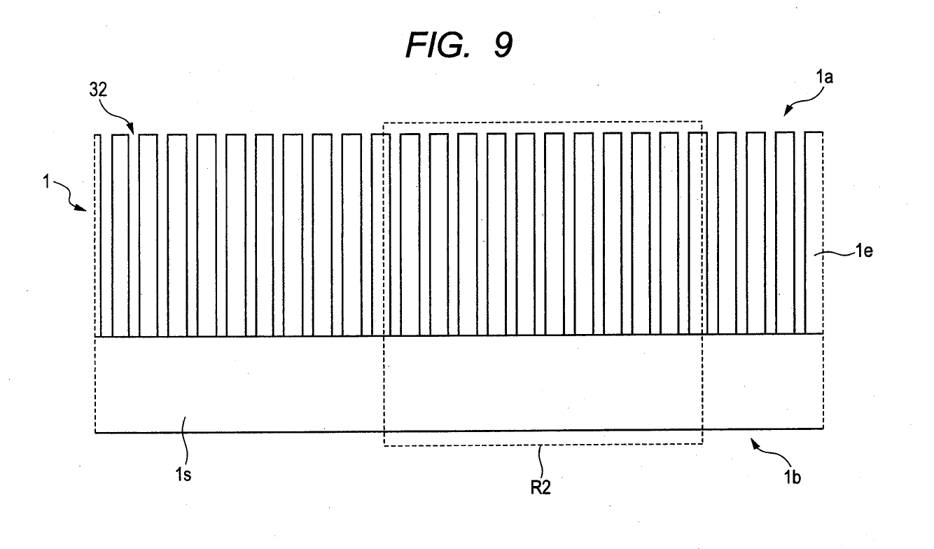

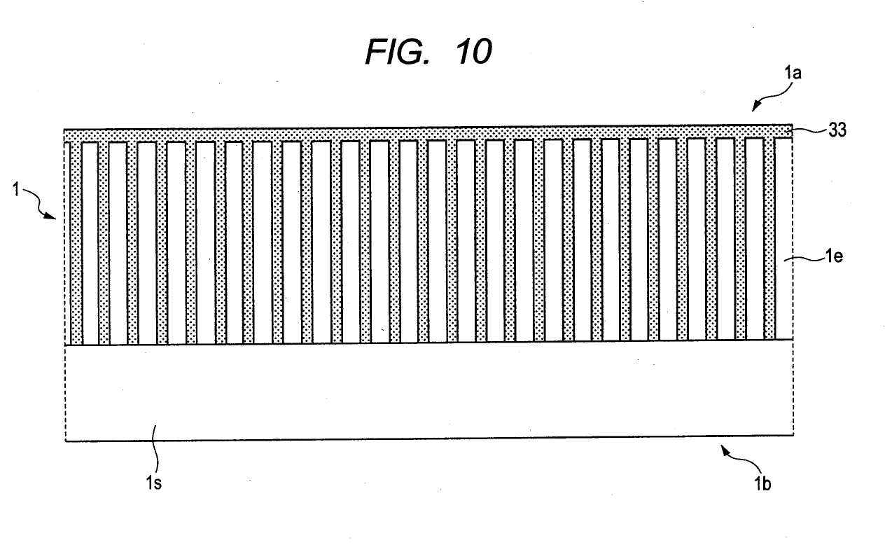

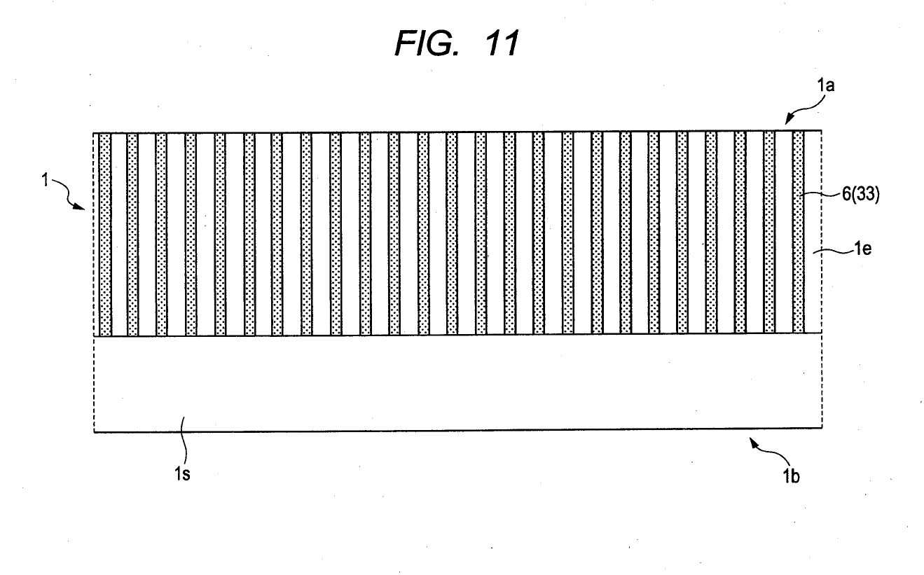

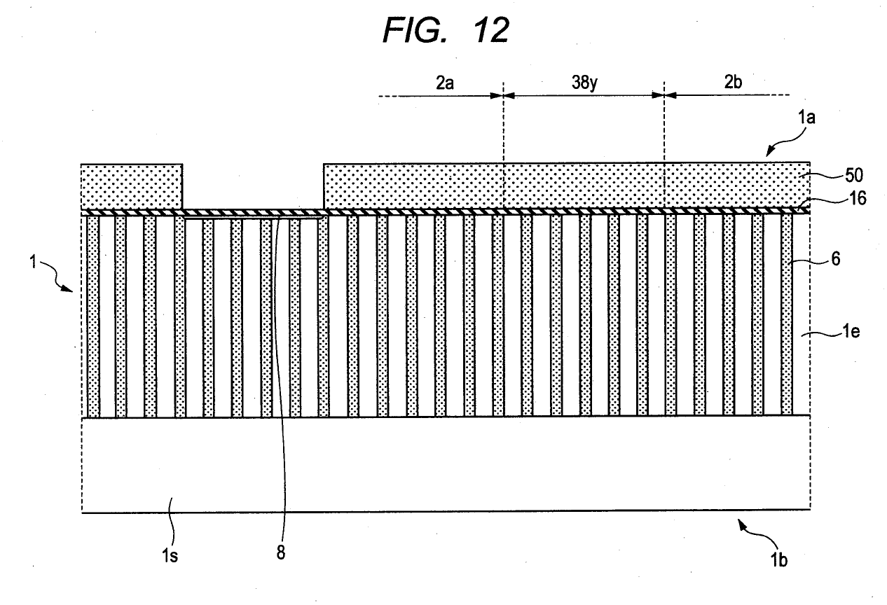

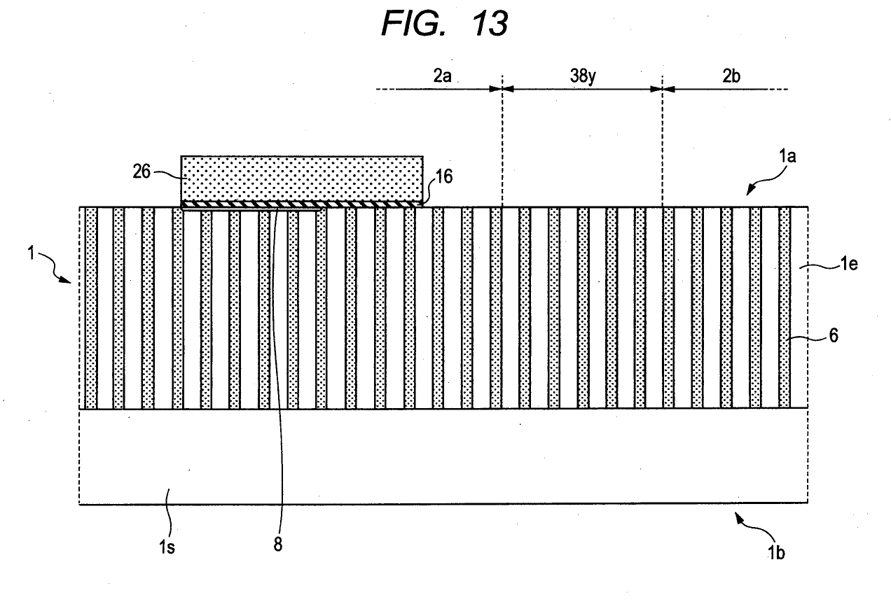

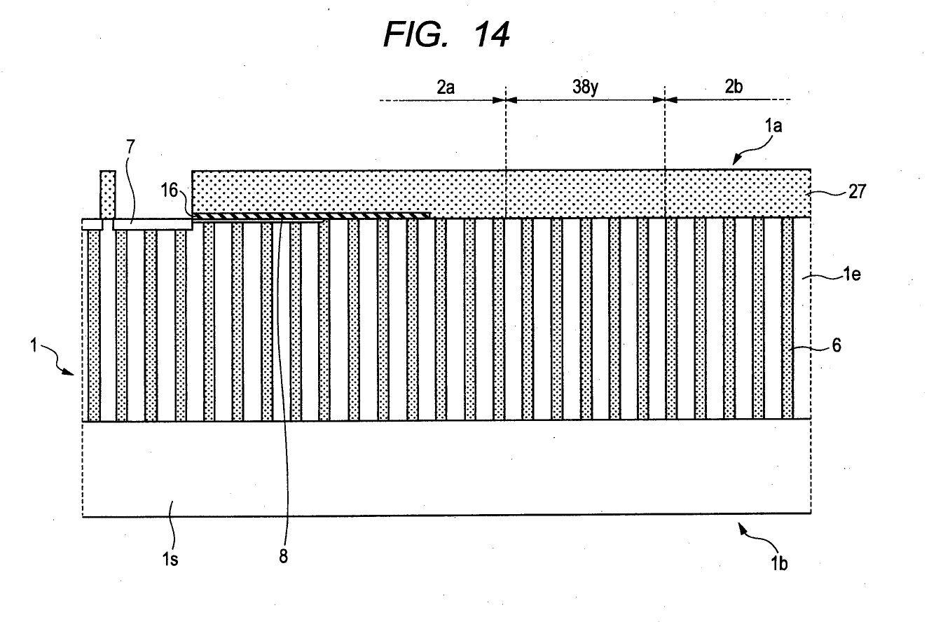

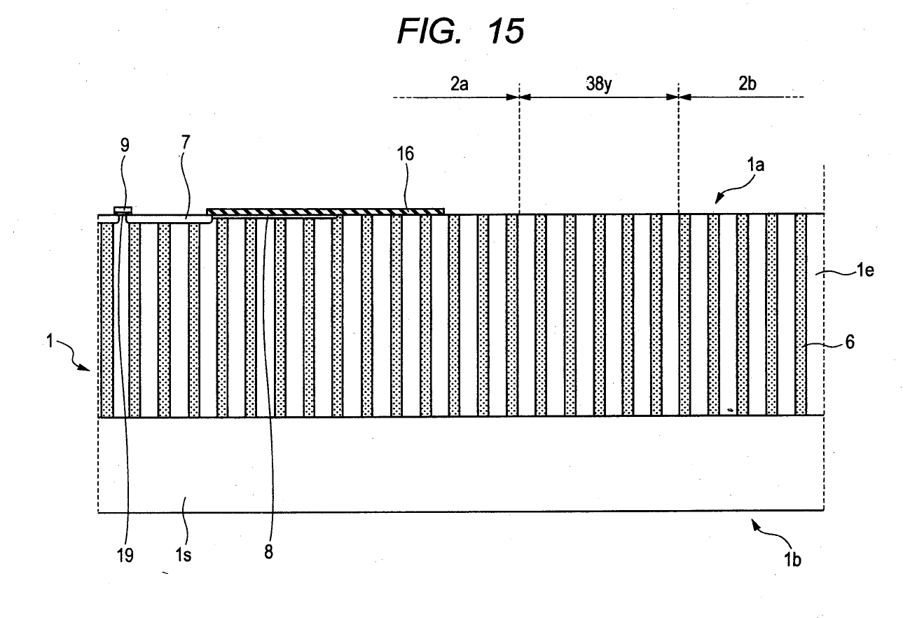

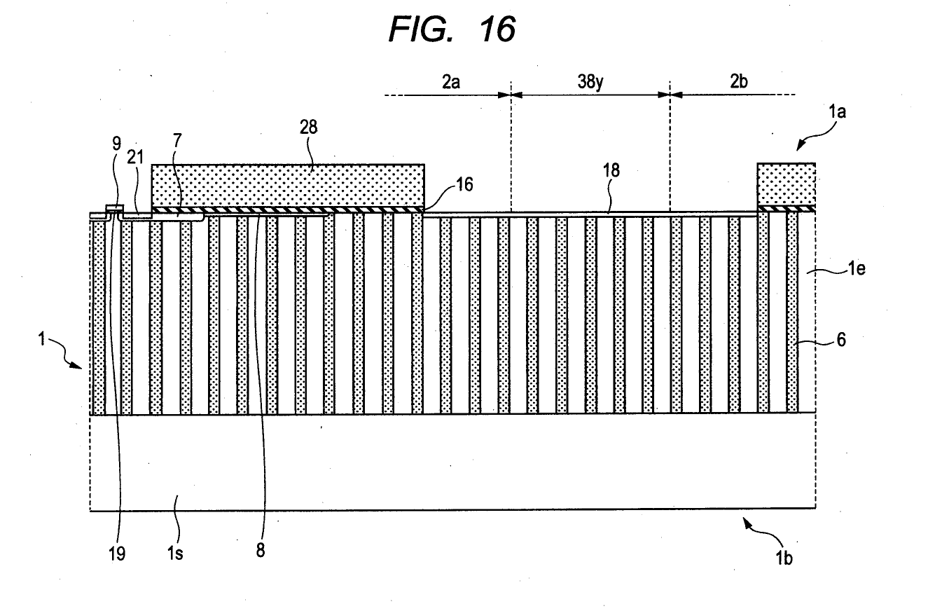

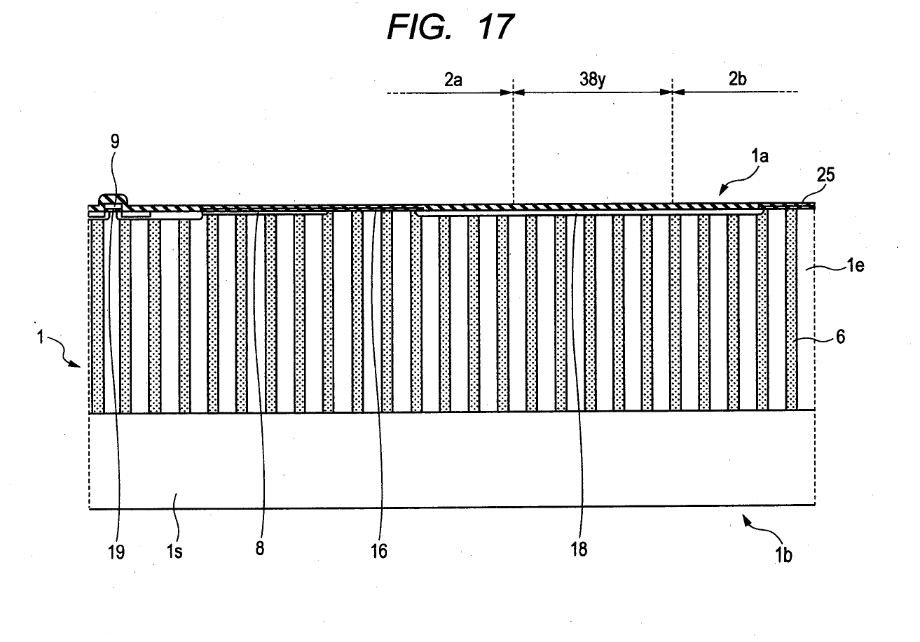

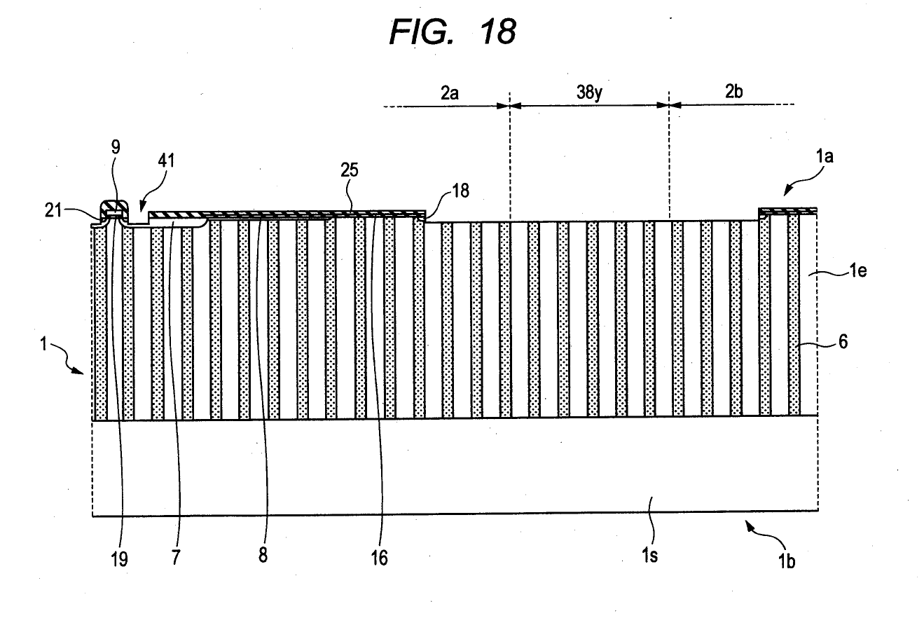

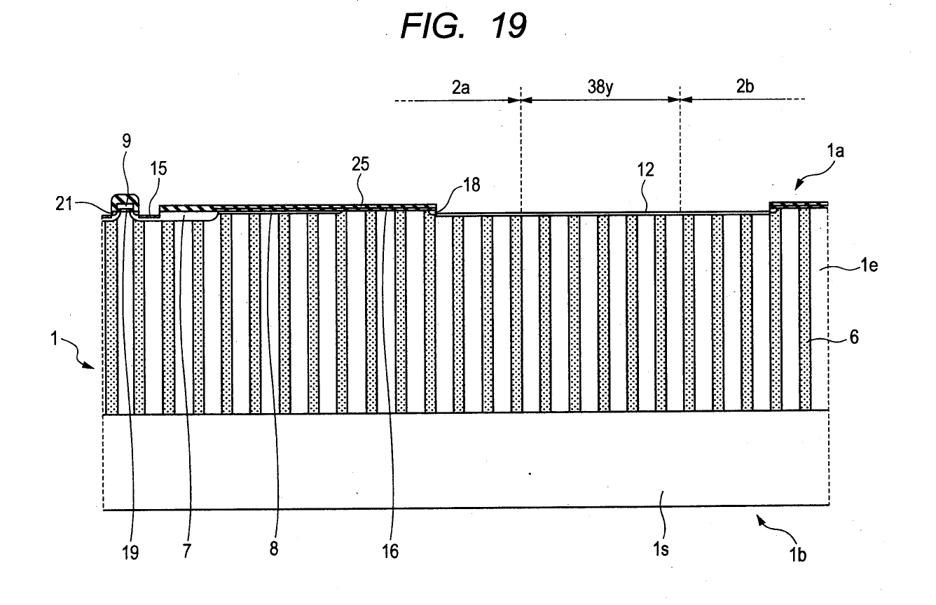

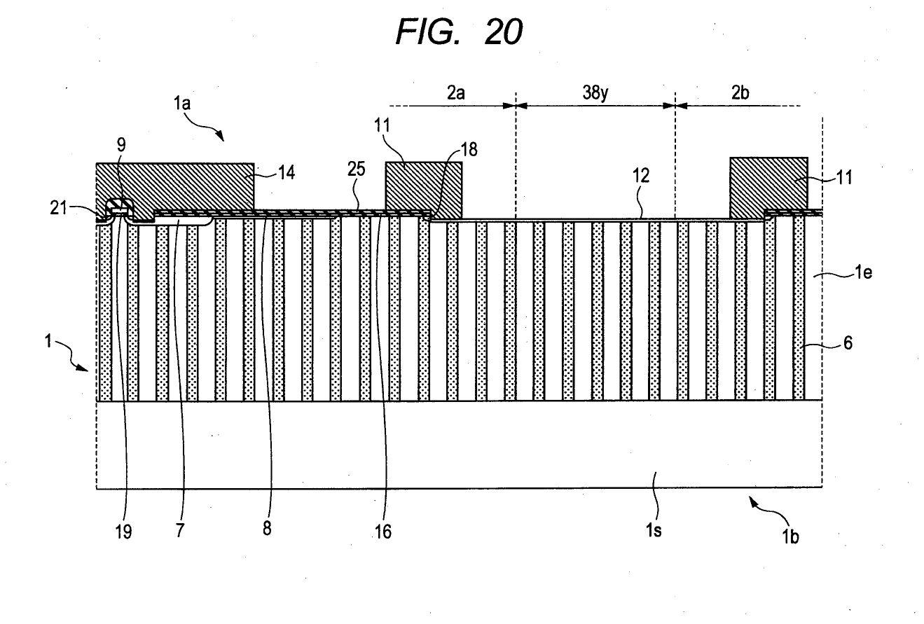

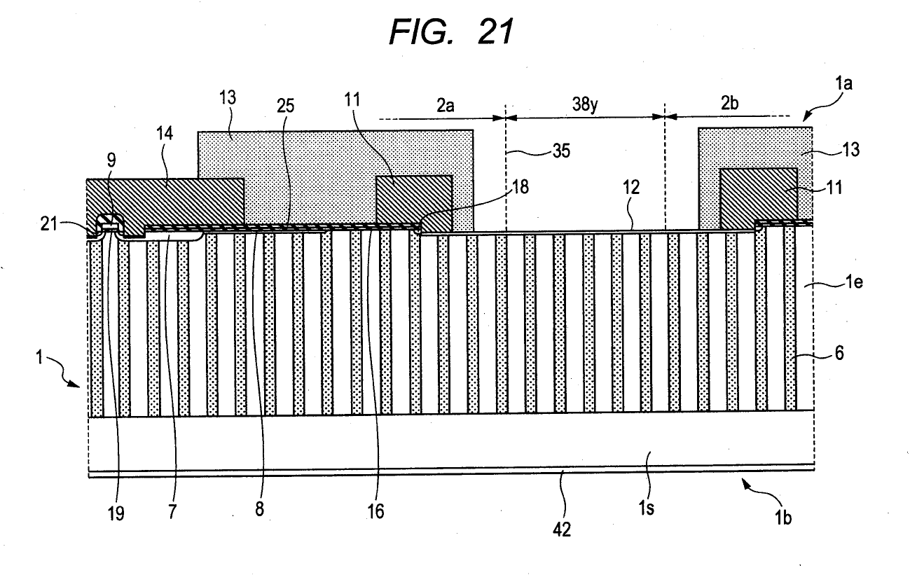

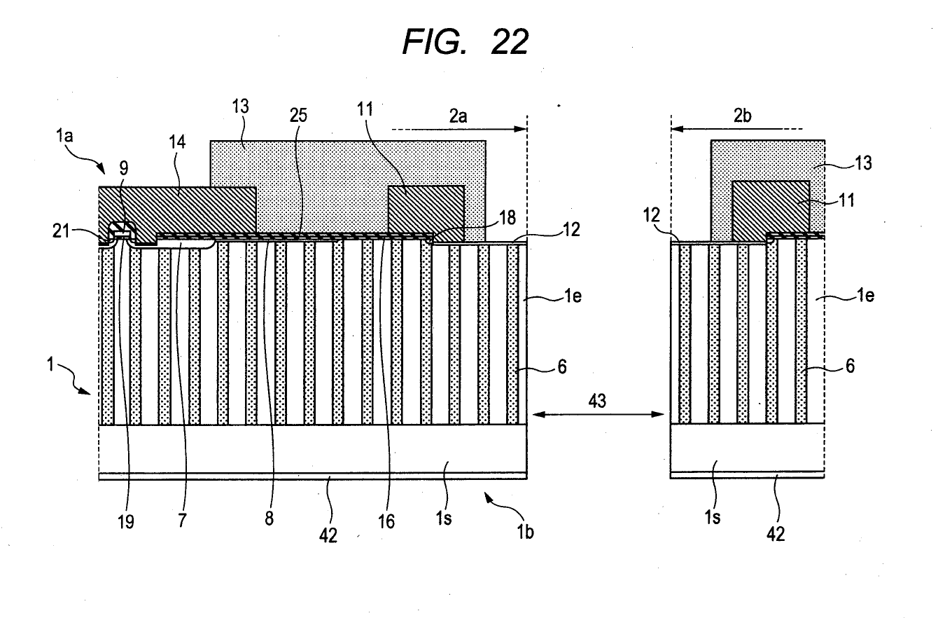

FIG. 7 is a partial sectional view of the wafer in a wafer process (a P type column trench-forming hard mask film forming step) corresponding to X-X′ section (showing up to near the guard ring in an adjacent chip region) in connection with a method for manufacturing the semiconductor device according to the first embodiment. FIG. 8 is a partial sectional view of the wafer in the wafer process (a P type column trench-forming hard mask film patterning step) corresponding to X-X′ section (showing up to near the guard ring in the adjacent chip) in FIG. 5 in connection with the method for manufacturing the semiconductor device according to the first embodiment. FIG. 9 is a partial sectional view of the wafer in the wafer process (a P type column trench forming step) corresponding to X-X′ section (showing up to near the guard ring in the adjacent chip region) in FIG. 5 in connection with the method for manufacturing the semiconductor device according to the first embodiment. FIG. 10 is a partial sectional view of the wafer in the wafer process (a P type burying epitaxial growth step) corresponding to X-X′ section (showing up to near the guard ring in the adjacent chip region) in FIG. 5 in connection with the method for manufacturing the semiconductor device according to the first embodiment. FIG. 11 is a partial sectional view of the wafer in the wafer process (a planarization step) corresponding to X-X′ section (showing up to near the guard ring in the adjacent chip region) in FIG. 5 in connection with the method for manufacturing the semiconductor device according to the first embodiment. FIG. 12 is a partial sectional view of the wafer in the wafer process (a P⁻ type surface resurf region introducing step) corresponding to X-X′ section (showing up to near the guard ring in the adjacent chip region) in FIG. 5 in connection with the method for manufacturing the semiconductor device according to the first embodiment. FIG. 13 is a partial sectional view of the wafer in the wafer process (a filed insulating film etching step) corresponding to X-X′ section (showing up to near the guard ring in the adjacent chip region) in FIG. 5 in connection with the method for manufacturing the semiconductor device according to the first embodiment. FIG. 14 is a partial sectional view of the wafer in the wafer process (a P type body region introducing step) corresponding to X-X′ section (showing up to near the guard ring in the adjacent chip region) in FIG. 5 in connection with the method for manufacturing the semiconductor device according to the first embodiment. FIG. 15 is a partial sectional view of the wafer in the wafer process (a gate electrode forming step) corresponding to X-X′ section showing up to near the guard ring in the adjacent chip region) in FIG. 5 in connection with the method for manufacturing the semiconductor device according to the first embodiment. FIG. 16 is a partial sectional view of the wafer in the wafer process (an N⁺ source region introducing step) corresponding to X-X′ section (showing up to near the guard ring in the adjacent chip region) in FIG. 5 in connection with the method for manufacturing the semiconductor device according to the first embodiment. FIG. 17 is a partial sectional view of the wafer in the wafer process (an interlayer dielectric film forming step) corresponding to X-X′ section (showing up to near the guard ring in the adjacent chip region) in FIG. 5 in connection with the method for manufacturing the semiconductor device according to the first embodiment. FIG. 18 is a partial sectional view of the wafer in the wafer process (a body contact hole forming step) corresponding to X-X′ section (showing up to near the guard ring in the adjacent chip region) in FIG. 5 in connection with the method for manufacturing the semiconductor device according to the first embodiment. FIG. 19 is a partial sectional view of the wafer in the wafer process (a P⁺ type body contact region introducing step) corresponding to X-X′ section (showing up to near the guard ring in the adjacent chip region) in FIG. 5 in connection with the method for manufacturing the semiconductor device according to the first embodiment. FIG. 20 is a partial sectional view of the wafer in the wafer process (an upper surface metal electrodes forming step) corresponding to X-X′ section (showing up to near the guard ring in the adjacent chip region) in FIG. 5 in connection with the method for manufacturing the semiconductor device according to the first embodiment. FIG. 21 is a partial sectional view of the wafer in the wafer process (a final passivation forming, back grinding and lower surface metal electrode forming step) corresponding to X-X′ section (showing up to near the guard ring in the adjacent chip region) in FIG. 5 in connection with the method for manufacturing the semiconductor device according to the first embodiment. FIG. 22 is a partial sectional view of the wafer in the wafer process (a dicing step) corresponding to X-X′ section (showing up to near the guard ring in the adjacent chip region) in FIG. 5 in connection with the method for manufacturing the semiconductor device according to the first embodiment. With reference to these figures, a description will be given below about the wafer process, etc. in the method for manufacturing the semiconductor device according to the first embodiment.

First, as shown in FIG. 7, there is provided a semiconductor wafer 1 formed for example on an antimony-doped (e.g. , of the order of about 10¹⁸ to 10¹⁹ cm³) N⁺ silicon single crystal substrate 1s (e.g., a 200φ) wafer, the wafer diameter may be 150φ), 300φ, or 450φ) with a phosphorus-doped N epitaxial layer 1e (drift region, having a concentration of, for example, the order of 10¹⁵/cm³ or so) about 45 micrometers in thickness. On a device surface 1a (a main surface opposite to a back surface 1b) of the semiconductor wafer 1 is formed a P type column trench forming hard mask film 31 using, for example, P-TEOS (Plasma-Tetraethylorthosilicate).

Then, as shown in FIG. 8, the P type column trench forming hard mask film 31 is subjected to patterning by, for example, conventional lithography to give hard mask film portions, for example, 6 micrometers in width and spaced, for example, 4 micrometers from each other.

Next, with the P type column trench forming hard mask film 31 as a mask, the N epitaxial layer 1e, etc. are subjected to dry etching (a mixed gas atmosphere comprised of argon, oxygen and SF₆ can be mentioned as an example of an etching gas atmosphere) to form P type column trenches 32 (the etching is performed at a depth such that the trenches reach the substrate 1s). Subsequently, the hard mask film 31 which has become unnecessary is removed.

Then, as shown in FIG. 10, burying epitaxial growth is performed for the P type column trenches 32 (using a vapor phase growth gas using, for example, silicon tetrachloride, trichlorosilane, dichlorosilane, or monosilane, as feed gas) to form a P type buried epitaxial layer 33 (using boron as dopant with a concentration of the order of, for example, 10¹⁵/cm³ or so).

Next, by a planarization step, for example by CMP (Chemical Mechanical Polishing) , as shown in FIG. 11, the P type buried epitaxial growth layer 33 located outside the P type column trenches 32 is removed and the surface la of the semiconductor wafer 1 is made flat. Such a super junction structure as shown in FIG. 11 may be formed not only by the trench filling method but also by a multi-epitaxial method.

Then, as shown in FIG. 12, a silicon oxide film 16 is formed substantially throughout the whole of the surface la of the semiconductor wafer 1 by thermal oxidation and a P⁻ type resurf region introducing resist film 50 is formed on the silicon oxide film 16 by lithography. Subsequently, a P⁻ type surface resurf region 8 is introduced by ion (e.g. boron) implantation with the P⁻ type resurf region introducing resist film 50 as a mask. Thereafter, the resist film 50 which has become unnecessary is removed throughout the whole surface thereof.

Next, as shown in FIG. 13, a filed insulating film processing resist film 26 is formed on the field oxide film 16 by lithography, and with the resist film 26 as a mask, the chip end portions and the active cell region are exposed. Thereafter, the resist film 26 which has become unnecessary is removed throughout the whole surface thereof.

Subsequently, as shown in FIG. 14, a P type body region introducing resist film 27 is formed on the surface la of the semiconductor wafer 1 by lithography, and with the resist film 27 as a mask, a P type body region 7 is introduced by ion implantation (using boron as dopant). For example, this ion implantation is performed in two steps as follows. In the first step, implantation is performed on the order of, for example, 200 keV, 10¹³/cm², then in the second step, implantation is performed on the order of, for example, 75 keV, 10¹²/cm². Thereafter, the resist film 27 which has become unnecessary is removed throughout the whole surface thereof.

According to the non-self-aligning P type body region introducing process used, the impurity already gets into the portion to serve as a gate electrode about one micrometer for example at the time of doping, so it is possible to lighten the burden of a later heat treatment. Consequently, it is possible to diminish an undesired change in impurity distribution of super junction. However, as a side effect, the voltage-proofing (or breakdown voltage) may be deteriorated as a result of the P type body region 7 becoming smaller in width. Therefore, the occurrence of such a problem is avoided by adopting the foregoing two-step ion implantation for the P type body region 7.

If the introduction of the P type body region 7 of a second conductivity type is thus performed prior to formation of a gate polysilicon film, the introducing portion is not limited by the gate width and position, so that the body region 7 can be introduced in an optimum position and it is possible to lighten the burden of the subsequent heat treatment; besides, it becomes possible to use the subsequent heat treatment (including the formation of a gate polysilicon film) in common. This non-self-aligning P type body region introducing process is applicable not only to the case where the ordinary epitaxial layer serving as a base for forming the super junction is comprised of multiple layers but also to the case where it is a single layer.

Next , as shown in FIG. 15, a gate oxide film 19 (having a thickness of, for example, 50 to 200 nm) is formed on the surface 1a of the semiconductor wafer 1 by thermal oxidation (e.g. , wet oxidation at 950° C.) . Then, a gate polysilicon film 11 (having a thickness of, for example, 20 to 800 nm) is formed by low pressure CVD (Chemical Vapor Deposition). As wafer cleaning before gate oxidation it is possible to adopt, for example, a wet cleaning method using a first cleaning solution comprising ammonia, hydrogen peroxide and pure water at a volume ratio of 1:1:5 and a second cleaning solution comprising hydrochloric acid, hydrogen peroxide and pure water at a volume ratio of 1:1:6. Subsequently, a gate electrode 9 is patterned by dry etching.

Then, as shown in FIG. 16, an N⁺ source region introducing resist film 28 is formed by lithography, and with the resist film 28 as a mask, an N⁺ source region 21 and a chip edge N⁺ type channel stopper region 18 are introduced by ion (e.g., arsenic) implantation (for example, dopant is arsenic, dose is on the order of 10¹⁵/cm², and implantation energy is 40 keV or so). Thereafter, the resist 28 film which has become unnecessary is removed throughout the whole surface thereof.

Next, as shown in FIG. 17, a PSG (Phospho-Siicate-Glass) film 25 (interlayer dielectric film) is formed by for example CVD substantially throughout the whole of the surface 1a of the semiconductor wafer 1 (SOG film may be superimposed on the film 25 and planarized). As examples of the interlayer dielectric film 25 there are mentioned not only PSG film but also BPSG film, TEOS film, SiN film, and composites thereof. An overall thickness of the interlayer dielectric film 25 is, for example, 900 nm or so.

Then, as shown in FIG. 18, a source contact hole opening resist film is formed on the surface la of the semiconductor wafer 1, and with the resist film as a mask, there are formed a source contact hole 41 and a chip edge aperture. Subsequently, the resist film which has become unnecessary is removed throughout the whole surface thereof. Further, with the patterned interlayer dielectric film 25 as a mask, the substrate surface is etched (to a depth of, for example, 0.3 micrometer) by anisotropic dry etching to form a recess region.

Next, as shown in FIG. 19, by implanting ions into the recess region there are formed a P⁺ type body contact region 15 and an outermost periphery P⁺ type region 12. Conditions for this ion implantation include for example: dopant BF2, implantation energy 30 keV or so, dose of the order of 10¹⁵/cm².

Then, as shown in FIG. 20, an aluminum-based metal layer is formed for example by sputtering through a barrier metal film such as TiW film, followed by patterning, to form a metal source electrode 14 and a guard ring electrode 11.

Next, as shown in FIG. 21, a final passivation film 13 such as, for example, an inorganic final passivation film or an organic/inorganic final passivation film is formed as an upper layer and a source pad aperture and a gate pad aperture 49 are formed. As the final passivation film there may be used not only a single layer film such as an inorganic final passivation film or an organic/inorganic final passivation film but also a laminate of an inorganic passivation film as a lower layer and an organic/inorganic final passivation film as an upper layer. Subsequently, by back grinding, the thickness of the wafer substrate portion (exclusive of the epitaxy portion because the thickness of the epitaxy portion varies greatly depending on the product type) is made, for example, about 200 to 20 micrometers from the original thickness of, for example, about 900 micrometers. Further, a back surface metal electrode 42 is formed on a back surface 1b of the wafer 1 by sputtering.

Then, as shown in FIG. 22, the wafer 1 is divided into individual chip regions 2 by, for example, blade dicing (laser dicing, laser grooving, or a combination thereof with blade dicing, will also do).

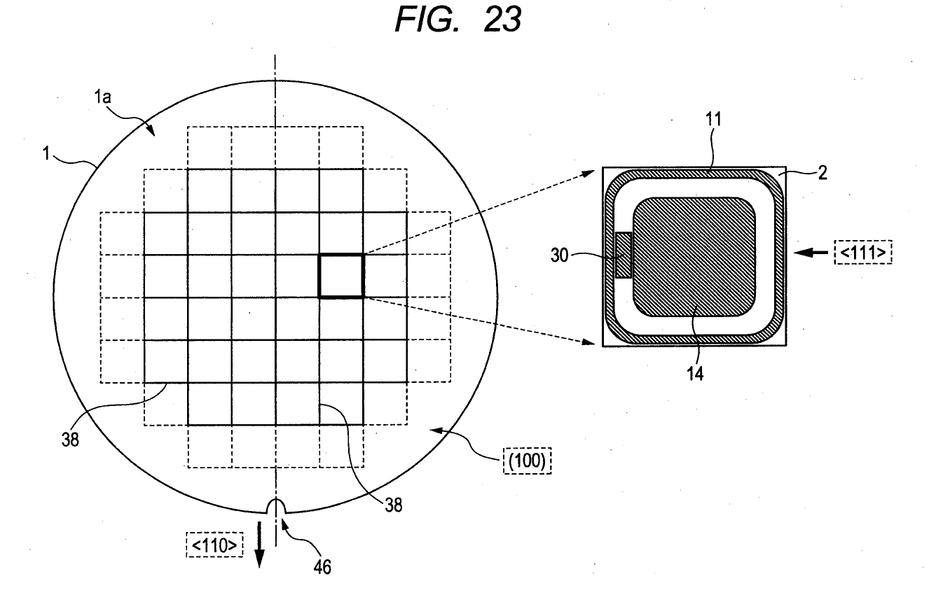

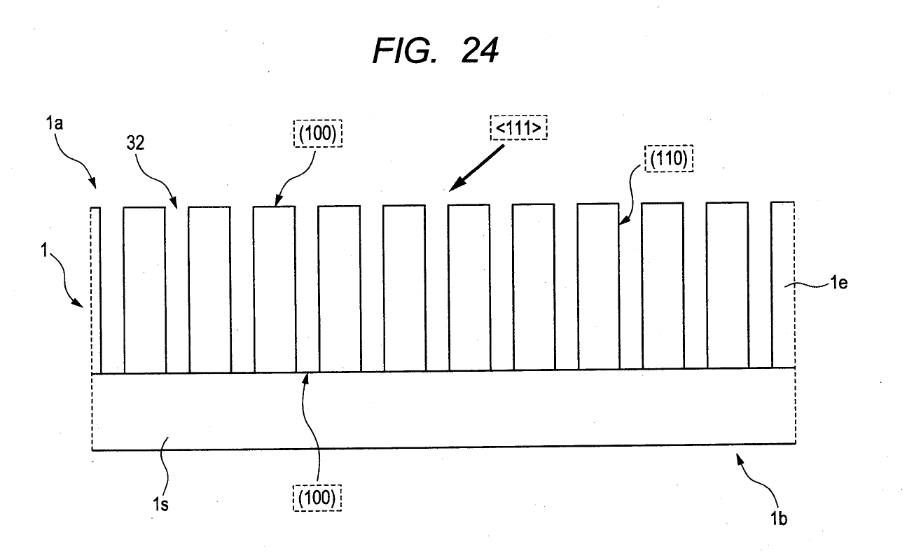

3. Explanation of Wafer Crystal Orientation, etc. in the method for manufacturing the semiconductor device according to the first embodiment (see mainly FIGS. 23 and 24):

In this section, in order to clarify the explanation of a crystal defect in the silicon epitaxy layer on the silicon single crystal wafer referred to above in sections 1 and 2, a brief description will be given about plane orientation and crystal orientation of the silicon single crystal wafer and the silicon epitaxy layer both used above in the embodiment. It goes without saying that the embodiments of the present invention are not limited to the plane orientation and crystal orientation as described here. The plane orientation and the crystal orientation both used herein include planes and directions equivalent thereto.

FIG. 23 is a top view of the entire wafer for explaining crystal orientation, etc. of the wafer in for example the method for manufacturing the semiconductor device according to the first embodiment. FIG. 24 is a partial sectional view of the wafer (corresponding to a wafer section cut-off region R2 in FIG. 9) for explaining a relation between wafer crystal orientation, etc. and each face of a trench in the method for manufacturing the semiconductor device according to the first embodiment. With reference to these figures, a description will be given below about wafer crystal orientation, etc. in the method for manufacturing the semiconductor device according to the first embodiment.

In the embodiments of the present invention, as shown in FIGS. 23 and 24, reference is made as an example mainly to the case where the plane orientation of the surface-side main surface 1a (device surface or first main surface) of the wafer 1 is (100) and the crystal orientation in the direction of a notch 46 (orientation flat will do) is <110> (provided crystal orientation <100> is used depending on device) . In an N channel type device, the surface-side main surface la is made (100) plane in many cases because electron mobility is large. When the notch 46 is crystal orientation <110>, a side face of each P type column burying trench 32 becomes (110) plane. Under such conditions, the <110> direction, which is a running direction of a line defect originating in a surface depression, substantially coincides with the direction of each arrow in FIGS. 23 and 24.

Generally, in the semiconductor wafer process, a large number of chip regions 2 (generally plural numbers, but ten-odd numbers to several thousand on the average) isolated from one another by longitudinal and lateral scribing lines are formed in a generally matrix shape on the surface-side main surface 1a of the wafer 1 and thereafter the wafer is cut, for example diced, along the scribing lines to form cut grooves or linear degenerated layers, thereby separating the wafer into individual chips.

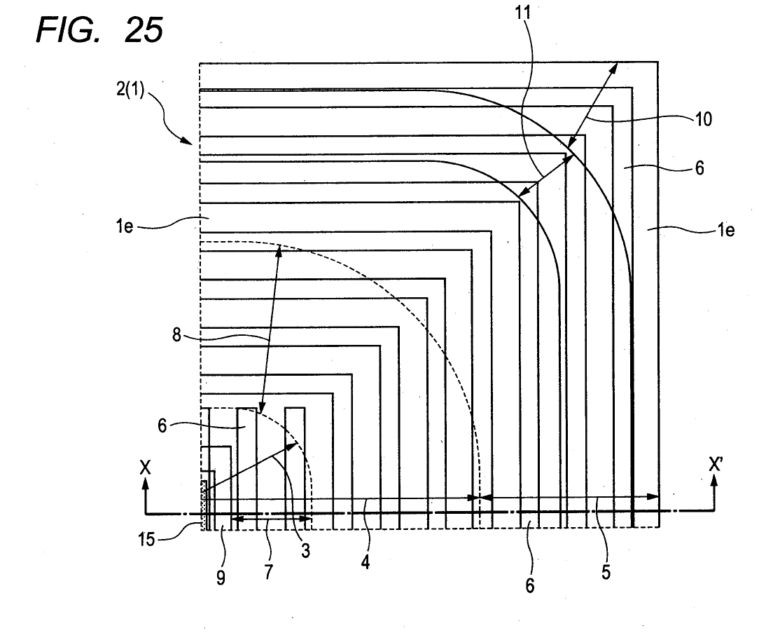

4. Explanation of Modification 1 (a two-dimensional resurf structure) related to a planar layout of a power MOSFET device structure as an example of the semiconductor device according to the first embodiment (see mainly FIG. 25):

An example to be described in this section is a modification of the P type column region layout of FIG. 3 (layout in the region outside the active cell region 3), i.e., super junction structure layout. The layout to be described is basically the same as the layout of FIG. 3 in point of both being a two-dimensional resurf structure (the dimensions in which a breakdown voltage holding depletion layer extends are two dimensions comprising a normal direction from the chip center to each side and the chip thickness direction).

FIG. 25 is a partial enlarged schematic layout diagram of device chip upper surface impurity regions, etc. corresponding to FIG. 3 for explaining a modification 1 (a two-dimensional resurf structure) related to a planar layout of a power MOSFET device structure as an example of the semiconductor device according to the first embodiment. With reference to FIG. 25, a description will be given below about a modification 1 (a two-dimensional resurf structure) related to a planar layout of a power MOSFET device structure as an example of the semiconductor device according to the first embodiment.

According to the structure of this modification 1, as shown in FIG. 25, deterioration of voltage-proofing at a chip corner is prevented by enhancing the symmetry of the P type column region layout.

The other portions than the portion just described above are the same as those described above in sections 1 to 3.

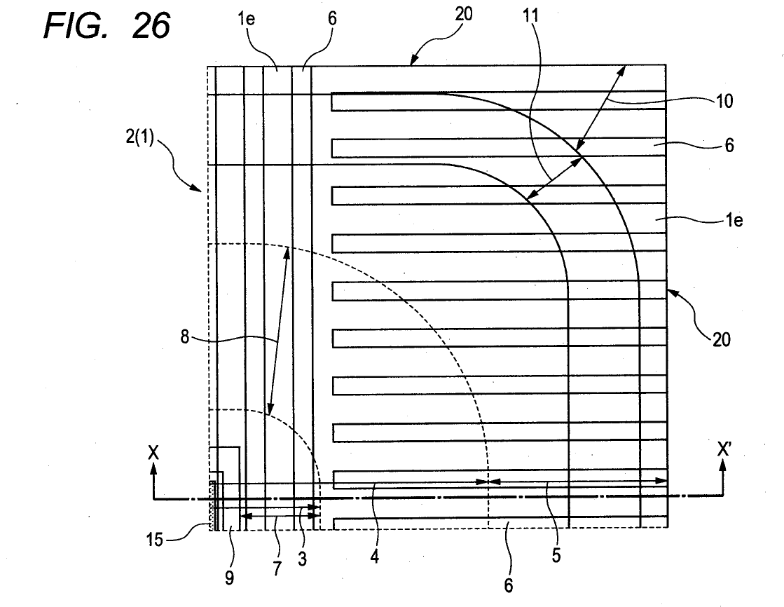

5. Explanation of Modification 2 (a three-dimensional resurf structure) related to a planar layout of a power MOSFET device structure as an example of the semiconductor device according to the first embodiment (see mainly FIG. 26):

An example to be described in this section is a modification of the P type column region layout of FIG. 3 (layout in the region outside the active cell region 3), i.e., super junction structure layout. However, unlike the examples of FIGS. 3 and 25, this modification 2 relates to a three-dimensional resurf structure (the dimensions in which a breakdown voltage holding depletion layer extends are three dimensions comprising a normal direction from the chip center to each side, a direction orthogonal thereto, and the chip thickness direction).

FIG. 26 is a partial enlarged schematic layout diagram of device chip upper surface impurity regions, etc. corresponding to FIG. 3 for explaining a modification 2 (a three-dimensional resurf structure) related to a planar layout of a power MOSFET device structure as an example of the semiconductor device according to the first embodiment. With reference to FIG. 26, a description will be given below about a modification 2 (a three-dimensional resurf structure) related to a planar layout of a power MOSFET device structure as an example of the semiconductor device according to the first embodiment.

As shown in FIG. 26, in the region between the active cell region 3 and each side of the chip, P type column regions 6 are arranged in a normal direction to each side from the chip center.

At a chip corner portion, modifications for enhancing various symmetries may be made as in section 4. The other portions than the portion described here are the same as those described above in sections 1 to 4.

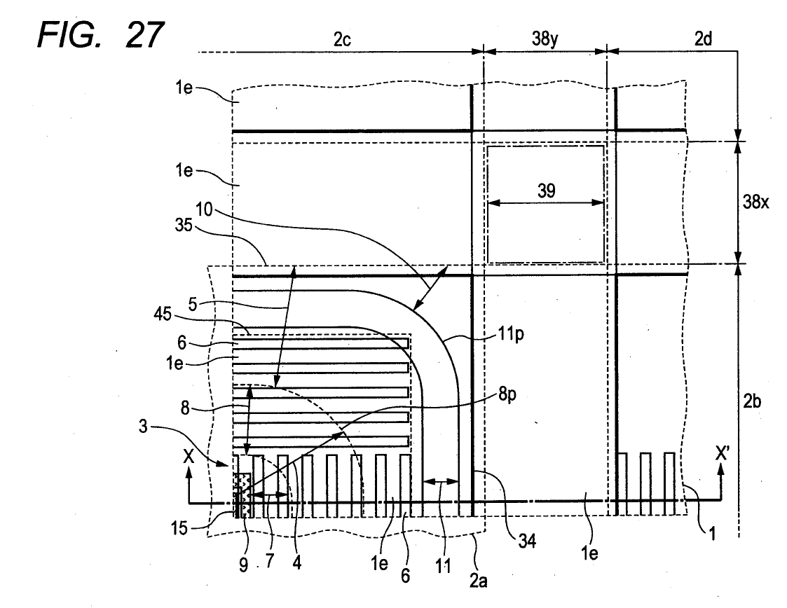

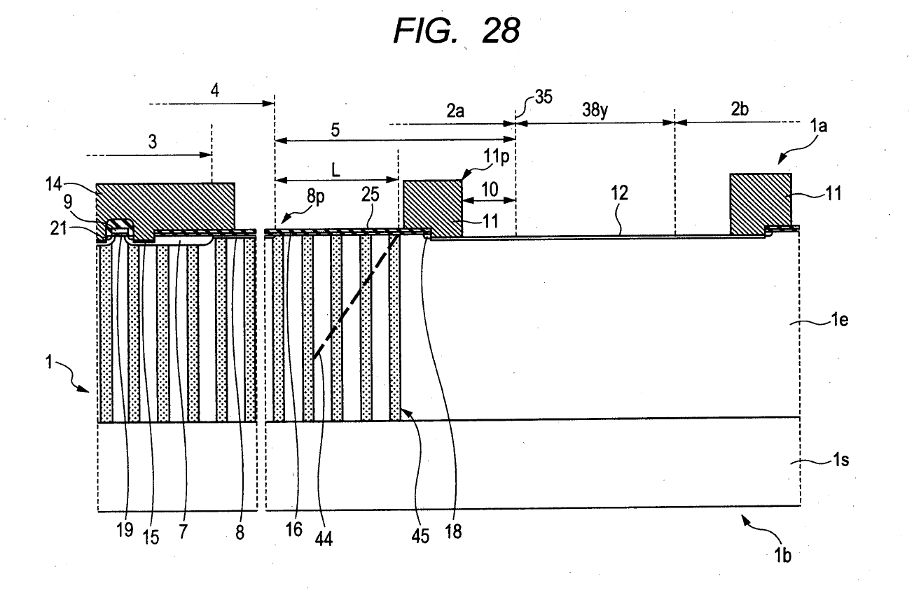

6. Explanation of Power MOSFET Device Structure (a two-dimensional resurf structure) as an example of the semiconductor device according to the second embodiment (see mainly FIGS. 27 and 28):

In the first embodiment the super junction structure is disposed substantially throughout the whole surface of the chip region 2 beyond the outer ends 34 of the chip region on the mask pattern, but in the example of this section, outer ends 45 of the super junction structure and an outer periphery 8p of the cell region periphery impurity doped region 8 which is closely concerned in voltage-proofing are isolated a predetermined certain distance or more from each other.

The other portions than those to be described below, including entire structure and manufacturing method, are basically the same as in sections 1 to 5 and therefore explanations thereof will be omitted. That is, only different portions will be described below.

FIG. 27 is a partial enlarged schematic layout diagram of wafer upper surface impurity regions in and around a corner portion of a chip region on a wafer corresponding to FIG. 5 for explaining a device structure (a two-dimensional resurf structure) of a power MOSFET as an example of a semiconductor device according to a second embodiment of the present invention. FIG. 28 is a sectional view of the wafer corresponding to X-X′ section (showing up to near a guard ring in an adjacent chip region) in FIG. 27. With reference to these figures, a power MOSFET device structure (a two-dimensional resurf structure) as an example of the semiconductor device of the second embodiment will be described.

As shown in FIGS. 27 and 28, outer ends 45 (outside an outermost P type column region) of the super junction structure and a cell region periphery impurity doped region 8 (more particularly, a P⁻ type surface resurf region for example) which is closely related to voltage-proofing are isolated a predetermined certain distance (isolation distance L) or more from each other. The isolation distance L can be set, for example, to 40 micrometers or more.

A line defect 44 extends a maximum of 30 micrometers or so obliquely downwards at an angle of approximately 45° from an upper surface of an N type epitaxial layer 1e (a drift region having a first conductivity type) near an outer end 45 of the super junction structure. Therefore, the line defect 44 is not presumed to reach the outer periphery 8p of the P⁻ type surface resurf region insofar as the isolation distance is 40 micrometers or more.

Consequently, it follows that the super junction structure need not be formed outside the guard ring.

7. Supplementary Explanation and Study about the embodiments (see mainly FIGS. 5 and 27):

An exact cause of a line defect contiguous with a depression formed in the chip surface near an outer end of the super junction structure, which has been explained previously, is not certain, but in the trench filling method it is evident that a fine silicon depression occurs near the surface of the outermost P type column region, resulting in a line defect of a relatively large size growing derivatively. In the first embodiment, therefore, the super junction structure is disposed substantially throughout the whole area on the wafer corresponding to a product area up to an actual outer end 35 of the chip region beyond an outer end 34 of the chip region on the mask pattern (exclusive of a part of the scribing lines 38 in, for example, the aligning pattern forming region 39), thereby expelling a depression-formed position to the exterior of the chip region 2.

On the other hand, in the second embodiment, there is ensured a sufficient distance from the outer periphery 8p of the cell region periphery impurity doped region 8 (a voltage-proofing sensitive structure) such as the P⁻ type surface resurf region which contributes sensitively to voltage-proofing, thereby preventing a line defect from reaching the voltage-proofing sensitive structure.

Though not essential, as shown in sections 1 to 6, if the P type column regions 6 are made almost equal in width and spacing within the super junction having the same orientation, there accrues a merit that the burying performance in the trench filling process is improved.

### 8. Summary

Although the present invention has been described above concretely by way of embodiments thereof, it goes without saying that the present invention is not limited to the above embodiments, but that various changes may be made within the scope not departing from the gist of the invention.

For example, although in the above embodiments reference has been made to the MOS structure of a planar type gate structure as an example, the present invention is not limited thereto. It goes without saying that the present invention is also applicable to a trench type gate structure completely in the same manner. Further, although an example has been shown above in which MOSFETs are arranged stripewise in parallel with pn column, they may be arranged in various other fashions such as, for example, in a direction orthogonal to pn column or in a lattice shape.

Although in the above embodiments a concrete description has been made mainly about an example in which an N channel device is formed on an upper surface of an N epitaxial layer formed on an N⁺ silicon single crystal substrate, the present invention is not limited thereto. A P channel device may be formed on an upper surface of a P epitaxial layer formed on a P⁺ silicon single crystal substrate.

Moreover, although in the above embodiments a description has been made concretely about a power MOSFET as an example, the present invention is not limited thereto. It goes without saying that the present invention is also applicable to power devices having a super junction structure such as, for example, diodes, bipolar transistors, and IGBTs (Insulated Gate Bipolar Transistors) and is further applicable to semiconductor integrated circuit devices incorporating those power MOSFETs, diodes, bipolar transistors, and IGBTs.

Further, although in the above embodiments a concrete description has been made mainly about the trench filling method as a method for forming the super junction structure, the present invention is not limited thereto. It goes without saying that the present invention is also applicable, for example, to a multi-epitaxial method.

What is claimed is:

1. A semiconductor device comprising:
(a) a semiconductor substrate having a first main surface and a second main surface and with a power semiconductor element formed thereover;
(b) a first electrode of the power semiconductor element provided on the first main surface side of the semiconductor substrate;
(c) a drift region of the power semiconductor element, the drift region being provided within the first main surface and having a first conductivity type; and
(d) a super junction structure formed substantially throughout the whole surface of the drift region, the super junction structure being provided substantially throughout the whole surfaces of end portions of the semiconductor substrate.

2. A semiconductor device according to claim 1, wherein the super junction structure reaches outer side faces of the semiconductor substrate.

3. A semiconductor device according to claim 2, further comprising:
(e) a guard ring formed over the first main surface of the semiconductor substrate so as to extend along an outer periphery of the first main surface.

4. A semiconductor device according to claim 3, wherein the super junction structure is provided substantially throughout the whole surface of the first main surface of the semiconductor substrate when seen in plan.

5. A semiconductor device according to claim 4, wherein the super junction structure is formed also exteriorly of the guard ring.

6. A semiconductor device according to claim 5, wherein the power semiconductor element is a power MOSFET.

7. A semiconductor device according to claim 5, wherein the power semiconductor element is a vertical power MOSFET.

8. A semiconductor device according to claim 7, wherein the super junction structure is formed by an epitaxy trench filling method.

9. A semiconductor device comprising:
(a) a semiconductor substrate having a first main surface and a second main surface and with a power semiconductor element formed thereover;
(b) a first electrode of the power semiconductor element , the first electrode being provided on the first main surface side of the semiconductor substrate;
(c) a drift region of the power semiconductor element, the drift region being provided within a surface on the first main surface side of the semiconductor substrate;
(d) a cell region of the power semiconductor element , the cell region being provided in a surface region on the first main surface side of the semiconductor substrate and, when seen in plan, in an inner region of the first main surface of the semiconductor substrate;
(e) a cell region periphery impurity doped region provided in the surface region on the first main surface side of the semiconductor substrate and, when seen in plan, at a periphery of the cell region so as to surround the cell region;
(f) a guard ring provided over and in a peripheral region of the first main surface of the semiconductor substrate so as to surround the cell region periphery impurity doped region; and
(g) a super junction structure formed in the drift region inside an outer periphery of the guard ring when seen in plan, each outer end of the super junction structure extending more outwards 40 micrometers or more than an outer periphery of the cell region periphery impurity doped region.

10. A semiconductor device according to claim 9, wherein the cell region periphery impurity doped region is a surface resurf region.

11. A semiconductor device according to claim 10, wherein the super junction structure is formed by an epitaxy trench filling method.

12. A semiconductor device according to claim 11, wherein the power semiconductor element is a power MOSFET.

13. A semiconductor device according to claim 11, wherein the power semiconductor element is a vertical power MOSFET.

14. A method for manufacturing a semiconductor device, comprising the steps of:
(a) forming a super junction structure substantially throughout the whole of a first main surface of a semiconductor wafer having the first main surface and a second main surface;
(b) after the step (a) , forming over the first main surface a plurality of semiconductor chip regions each corresponding to a power semiconductor element and mutually isolated by scribing lines; and
(c) after the step (b), separating the semiconductor wafer along the scribing lines to divide the wafer into individual semiconductor chip regions.

15. A method according to claim 14, wherein the super junction structure is formed by an epitaxy trench filling method.

16. A method according to claim 15, wherein the power semiconductor element is a power MOSFET.

17. A method according to claim 16, wherein the super junction structure is formed substantially throughout the whole surface of each of the semiconductor chip regions and substantially throughout the whole surface within each of the scribing lines.

18. A method according to claim 17, wherein a guard ring is provided in a peripheral region within each of the semiconductor chip regions.

19. A method according to claim 18, wherein an alignment pattern forming region not formed with the super junction structure is present within each of the scribing lines.

20. A method according to claim 19, wherein the power semiconductor element is a vertical power MOSFET.
